(19) United States
(12) Patent Application Publication
(10) Pub. No.: US 2023/0371188 A1
(43) Pub. Date: Nov. 16, 2023

(54) INSULATING MATERIAL FOR CIRCUIT SUBSTRATE, AND METHOD FOR MANUFACTURING THE SAME, AND METAL FOIL-CLAD LAMINATE

(71) Applicant: Denka Company Limited, Chuo-ku, Tokyo (JP)

(72) Inventors: Shun UCHIYAMA, Tokyo (JP); Yusuke MASUDA, Tokyo (JP)

(73) Assignee: Denka Company Limited, Chuo-ku, Tokyo (JP)

(21) Appl. No.: 18/027,885

(22) PCT Filed: Sep. 21, 2021
(86) PCT No.: PCT/JP2021/034528

§ 371 Date: Mar. 22, 2023

(30) Foreign Application Priority Data
Sep. 23, 2020 (JP) 2020-158643

(51) Int. Cl. H05K 3/46; H05K 1/03

(52) U.S. Cl. CPC H05K 3/4632; H05K 1/03; H05K 2201/0129; H05K 2201/029; H05K 2201/0209; H05K 2203/06

(57) ABSTRACT

Provided are an insulating material for a circuit substrate, which has excellent dielectric characteristics in a high frequency area, has low coefficients of linear thermal expansion all in a MD direction, a TD direction, and a ZD direction, is easily manufactured and has excellent productivity, and a method for manufacturing the same and a metal foil-clad laminate. An insulating material for a circuit substrate, comprising a laminate having a thermoplastic liquid crystal polymer film and a woven fabric of an inorganic fiber, wherein the thermoplastic liquid crystal polymer film contains an inorganic filler, and the laminate is a dry laminate in which the thermoplastic liquid crystal polymer film and the woven fabric are thermocompression bonded.

### TECHNICAL FIELD

The present invention relates to an insulating material for a circuit substrate and a method for manufacturing the same, and a metal foil-clad laminate.

### BACKGROUND ART

A composite impregnated with varnish has been conventionally known as an insulating material for a circuit substrate, the composite being formed by impregnating a glass cloth with a varnish comprising a thermosetting resin such as an epoxy resin and an inorganic filler and then subjecting the resultant to heat press molding (see, e.g., Patent Literatures 1 to 2). However, such a procedure is poor in process tolerance during manufacturing and inferior in productivity from the viewpoint of, for example, resin fluidity during impregnation with varnish and curing ability during heat press molding. A thermosetting resin easily absorbs moisture, and is changed in dimension along with such moisture absorption, and the obtained composite impregnated with varnish is inferior in dimensional accuracy (heating dimensional accuracy).

Liquid crystal polymers (LCP) are polymers that exhibit liquid crystallinity in a molten state or a solution state. Especially, thermotropic liquid crystal polymers that exhibit liquid crystallinity in a molten state have excellent properties such as high gas barrier properties, high film strength, high heat resistance, high insulation properties, low water absorption, and low dielectric characteristics in a high frequency area. Therefore, films using liquid crystal polymers are studied to come into practical use in gas barrier film material applications, electronic material applications, and electrically insulating material applications. As a liquid crystal polymer film having such properties, a liquid crystal polymer film is disclosed which is obtained by inflation molding of a thermoplastic liquid crystal polymer as a copolymerized product of p-hydroxybenzoic acid and 6-hydroxy-2-naphthoic acid (see, e.g., Patent Literature 3).

However, films using liquid crystal polymers are high in anisotropy of molecular orientation in a film plane and large in in-plane anisotropy of the change in heating dimension. In order to improve this, a biaxially stretched liquid crystal polymer film is disclosed which is formed from a blended product of a liquid crystal polymer and at least one thermoplastic resin selected from the group consisting of polyethersulfone, polyetherimide, polyamideimide, polyether ether ketone, polyarylate and polyphenylene sulfide (see, e.g., Patent Literature 4).

Meanwhile, as an insulating material for a circuit substrate, using a liquid crystal polymer, a composite impregnated with varnish is known which is obtained by impregnating a glass cloth with a varnish comprising a liquid crystal polymer, an inorganic filler, a solvent, and the like and then subjecting the resultant to heat press molding (see, e.g., Patent Literature 5). As an insulating material for a circuit substrate without a varnish impregnation process, a laminated film is known which is obtained by thermocompression bonding of a liquid crystal polymer film and a glass cloth (see, e.g., Patent Literatures 6 to 7).

### CITATION LIST

### Patent Literature

Patent Literature 1: Japanese Patent Laid-Open No. 2017-052955

Patent Literature 2: Japanese Patent Laid-Open No. 2019-199562

Patent Literature 3: Japanese Patent Laid-Open No. 2000-263577

Patent Literature 4: Japanese Patent Laid-Open No. 2004-175995

Patent Literature 5: Japanese Patent Laid-Open No. 2010-103339

Patent Literature 6: Japanese Patent Laid-Open No. 09-309150

Patent Literature 7: Japanese Patent Laid-Open No. 2005-109042

### SUMMARY OF INVENTION

### Technical Problem

An insulating material for a circuit substrate using a liquid crystal polymer has excellent high frequency characteristics and low dielectric properties, and therefore has been spotlighted in recent years as an insulating material for a circuit substrate such as flexible printed wiring boards (FPC), flexible printed wiring board laminates, and fiber reinforced flexible laminates in the fifth-generation mobile communication system (5G), millimeter wave radar, and the like that will be developed in the future.

In the technique of Patent Literature 4 described above, the thermoplastic resin blended is biaxially stretched to thereby successfully suppress the coefficients of linear thermal expansion of the film in the MD direction (Machine Direction) and the TD direction (Transverse Direction) to 5 to 25 ppm/K, whereas the coefficient of linear thermal expansion of the film in the ZD direction (thickness direction) is still more than 200 ppm/K. For example, a reduction in coefficient of linear thermal expansion of the film in the ZD direction (thickness direction) is strongly required in rigid substrate applications in which multilayer laminates are required. Moreover, since a large amount of thermoplastic resins such as polyarylate are blended, the biaxially stretched film obtained in Patent Literature 4 has reduced heat resistance, dielectric characteristics, tensile strength, and the like, and lacks in practicality in terms of the basic performance required as the insulating material for a circuit substrate.

In the technique described in Patent Literature 5, since a varnish impregnation process is adopted, the process tolerance in manufacturing is poor from the viewpoint of, for example, the resin fluidity in impregnation with varnish and the curing ability in heat press molding, and not only productivity is inferior, but also the freedom of product constitution is poor, for example, the thickness of the thermoplastic liquid crystal polymer film is restricted. In addition, there is a large burden of facilities for, for example, drying of base materials impregnated with varnish and treatment of remaining solvents, and drying furnaces required therefor. Meanwhile, in the techniques described in Patent Literatures 6 to 7, the coefficient of thermal expansion or the like in the in-plane direction is reduced by thermocompression bonding of the liquid crystal polymer film and the glass cloth. However, the coefficient of linear thermal expansion in the ZD direction (thickness direction) is neither studied, nor addressed at all.

The present invention has been made in view of the above problems. An object of the present invention is to provide an insulating material for a circuit substrate, which has excellent dielectric characteristics in a high frequency area, has low coefficients of linear thermal expansion all in a MD direction, a TD direction, and a ZD direction, is easily manufactured and has excellent productivity, as well as a method for manufacturing the same, and a metal foil-clad laminate.

### Solution to Problem

The present inventors have intensively studied to solve the above problems, and as a result, have found that the above problems can be solved by a predetermined dry laminate in which a thermoplastic liquid crystal polymer film and a woven fabric of an inorganic fiber are thermocompression bonded, thereby completing the present invention.

That is, the present invention provides the various specific aspects shown below.
(1) An insulating material for a circuit substrate, comprising a laminate having a thermoplastic liquid crystal polymer film and a woven fabric of an inorganic fiber, wherein the thermoplastic liquid crystal polymer film contains an inorganic filler, and the laminate is a dry laminate in which the thermoplastic liquid crystal polymer film and the woven fabric are thermocompression bonded.
(2) The insulating material for a circuit substrate according to (1), wherein the thermoplastic liquid crystal polymer film is a melt-extruded film.
(3) The insulating material for a circuit substrate according to (1) or (2), wherein the thermoplastic liquid crystal polymer film is a T-die melt-extruded film.
(4) The insulating material for a circuit substrate according to any one of (1) to (3), wherein the inorganic filler contains silica.
(5) The insulating material for a circuit substrate according to any one of (1) to (4), wherein the inorganic filler has a median diameter (d50) of 0.01 μm or more and 50 μm or less.
(6) The insulating material for a circuit substrate according to any one of (1) to (5), wherein the thermoplastic liquid crystal polymer film contains 1% by mass or more and 45% by mass or less of the inorganic filler based on a total amount of the film.
(7) The insulating material for a circuit substrate according to any one of (1) to (6), wherein the woven fabric has a thickness of 10 μm or more and 300 μm or less.
(8) The insulating material for a circuit substrate according to any one of (1) to (7), wherein the woven fabric of the inorganic fiber is a glass cloth.
(9) The insulating material for a circuit substrate according to any one of (1) to (8), wherein an average coefficient of linear thermal expansion at 23 to 200° C., as measured by a TMA method according to JIS K7197, is 5 ppm/K or more and 25 ppm/K or less in an in-plane direction and 10 ppm/K or more and 100 ppm/K or less in a thickness direction.
(10) The insulating material for a circuit substrate according to any one of (1) to (9), wherein a relative dielectric constant εᵣ at 36 GHz, as measured by a cavity resonator perturbation method according to JIS K6471, is 3.0 or more and 3.7 or less.
(11) The insulating material for a circuit substrate according to any one of (1) to (10), wherein a dielectric loss tangent tan δ at 36 GHz, as measured by a cavity resonator perturbation method according to JIS K6471, is 0.0010 or more and 0.0050 or less.
(12) A method for manufacturing an insulating material for a circuit substrate, comprising a step of preparing a thermoplastic liquid crystal polymer film containing an inorganic filler, a step of preparing a woven fabric of an inorganic fiber, and a step of laminating the thermoplastic liquid crystal polymer film and the woven fabric, and heating and pressurizing the resultant, to thereby form a dry laminate in which the thermoplastic liquid crystal polymer film and the woven fabric are thermocompression bonded.
(13) The method for manufacturing an insulating material for a circuit substrate according to (12), wherein the step of preparing the thermoplastic liquid crystal polymer film comprises a step of preparing a resin composition containing the thermoplastic liquid crystal polymer and the inorganic filler, and a film formation step of molding the resin composition to thereby form the thermoplastic liquid crystal polymer film containing the inorganic filler.
(14) A metal foil-clad laminate comprising the insulating material for a circuit substrate according to any one of (1) to (11), and a metal foil(s) provided on one surface and/or both surfaces of the insulating material for a circuit substrate.

### Advantageous Effects of Invention

One aspect of the present invention can provide an insulating material for a circuit substrate, which has excellent dielectric characteristics in a high frequency area, has low coefficients of linear thermal expansion all in a MD direction, a TD direction, and a ZD direction, is easily manufactured and has excellent productivity, as well as a method for manufacturing the same, and a metal foil-clad laminate. One aspect of the present invention can also realize a high-performance insulating material for a circuit substrate without any varnish impregnation process, and thus can supply an insulating material for a circuit substrate stably with good reproducibility at a low cost.

### BRIEF DESCRIPTION OF DRAWINGS

FIG. 1 is a schematic cross-sectional view of an insulating material for a circuit substrate 100 of one embodiment.

FIG. 2 is a flow chart of a method for manufacturing an insulating material for a circuit substrate 100 of one embodiment.

FIG. 3 is a schematic view of a metal foil-clad laminate 200 of one embodiment.

### DESCRIPTION OF EMBODIMENTS

Hereinafter, the embodiments of the present invention will be described in detail with reference to the drawings. Unless otherwise indicated, the positional relationship, such as top, bottom, left, and right is based on the positional relationship shown in the drawings. Also, the dimensional ratios of the drawings are not limited to those illustrated in the drawings. It should be noted that the following embodiments are merely examples for explaining the present invention, and the present invention is not limited thereto. That is, the present invention can be appropriately modified and implemented within a range not departing from the gist of the present invention. As used herein, for example, the description of the numerical value range “1 to 100” includes both the lower limit value “1” and the upper limit value “100”. Also, the same applies to the description of other numerical value ranges.

### Insulating Material for Circuit Substrate

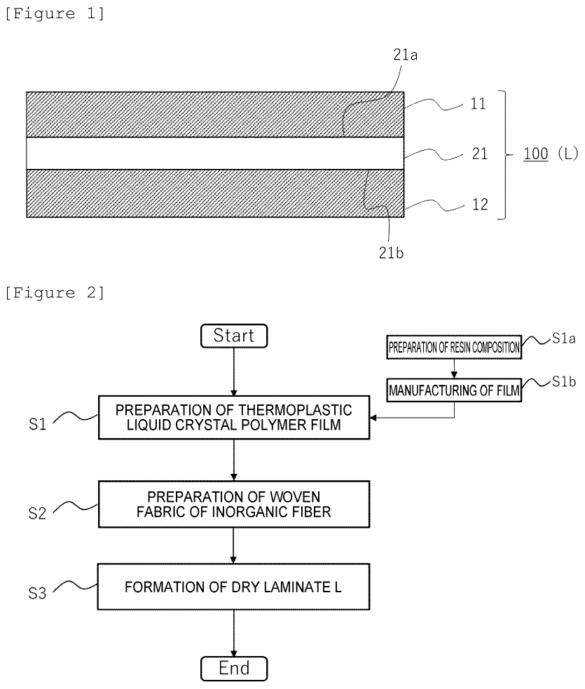

FIG. 1 is a schematic cross-sectional view of a main portion of an insulating material for a circuit substrate 100 of the present embodiment. The insulating material for a circuit substrate 100 of the present embodiment comprises a laminate having a laminated structure (three layer structure) in which a thermoplastic liquid crystal polymer film 11, a woven fabric of an inorganic fiber 21, and a thermoplastic liquid crystal polymer film 12 are at least arranged in the listed order. In the laminate, the thermoplastic liquid crystal polymer film 11 is provided on a surface 21a side of the woven fabric 21 and the thermoplastic liquid crystal polymer film 12 is provided on a surface 21b side of the woven fabric 21, and the thermoplastic liquid crystal polymer films 11 and 12 are thermocompression bonded with the woven fabric 21 and thus a dry laminate L of a three layer structure is formed, as described below. While the dry laminate L of a three layer structure is exemplified in the present embodiment, the present invention can be, of course, realized even by a dry laminate L of a two layer structure in which either the thermoplastic liquid crystal polymer film 11 or the thermoplastic liquid crystal polymer film 12 is omitted or a dry laminate L of a four or more layer structure in which the thermoplastic liquid crystal polymer films 11 and 12 and/or the woven fabric 21 are further laminated.

As used herein, the “at least arranged in the listed order” encompasses not only an aspect in which the thermoplastic liquid crystal polymer films 11 and 12 are placed directly on surfaces (e.g., surface 21a and surface 21b) of the woven fabric 21 as in the present embodiment, but also an aspect in which any layers (not shown, e.g., primer layer and adhesive layer) are interposed between the surfaces 21a, 21b of the woven fabric 21 and the thermoplastic liquid crystal polymer films 11 and 12 and thus the thermoplastic liquid crystal polymer films 11 and 12 are located with being apart from the surfaces 21a, 21b of the woven fabric 21.

The thermoplastic liquid crystal polymer films 11 and 12 are each obtained by molding a thermoplastic liquid crystal polymer into a film. As used herein, the “film” does not encompass a woven fabric and a non-woven fabric (hereinafter, sometimes collectively referred to as the “fabric”.). A melt-extruded film such as a T-die melt-extruded film is preferably used for the thermoplastic liquid crystal polymer films 11 and 12. A melt-extruded film of a thermoplastic liquid crystal polymer is available which is low in cost and homogeneous as compared with woven fabrics and non-woven fabrics made of thermoplastic liquid crystal polymer fibers.

The thicknesses of the thermoplastic liquid crystal polymer films 11 and 12 can be appropriately set depending on the desired performance and are not particularly limited. Considering the handleability and the productivity during melt extrusion and the like, the thicknesses are each preferably 5 μm or more and 300 μm or less, more preferably 10 μm or more and 250 μm or less, and further preferably 20 μm or more and 200 μm or less. The thicknesses of the thermoplastic liquid crystal polymer films 11 and 12 may be the same as or different from each other. In the present embodiment, a dry laminate L in which the thermoplastic liquid crystal polymer films 11 and 12 and the woven fabric 21 are thermocompression bonded is adopted, and therefore an advantage is that thick (e.g., thickness 200 μm or more) thermoplastic liquid crystal polymer films 11 and 12 which have not been able to be applied in a varnish impregnation process as a conventional technique can be applied.

As the thermoplastic liquid crystal polymer here used, those known in the art may be used, and the type thereof is not particularly limited. A liquid crystal polymer is a polymer that forms an optically anisotropic molten phase, and representative examples thereof include a thermotropic liquid crystal compound. The properties of the anisotropic molten phase can be confirmed by a known method such as a polarization test method using crossed polarizers. More specifically, the anisotropic molten phase can be confirmed by observing a sample placed on a Leitz hot stage with a Leitz polarization microscope under a nitrogen atmosphere at 40-fold magnification.

Specific examples of the thermoplastic liquid crystal polymer include those obtained by polycondensation of monomers such as aromatic or aliphatic dihydroxy compounds, aromatic or aliphatic dicarboxylic acids, aromatic hydroxycarboxylic acids, aromatic diamines, aromatic hydroxyamines, and aromatic aminocarboxylic acids, but are not particularly limited thereto. The thermoplastic liquid crystal polymer is preferably a copolymer. Specific examples include aromatic polyamide resins obtained by polycondensation of monomers such as aromatic hydroxycarboxylic acids, aromatic diamines, and aromatic hydroxyamines; and aromatic polyester resins obtained by polycondensation of monomers such as aromatic diols, aromatic carboxylic acids, and aromatic hydroxycarboxylic acids; but are not particularly limited thereto. The thermoplastic liquid crystal polymer can be used singly or in any combination of two or more thereof at any ratio. The thermoplastic liquid crystal polymer film 11 and the thermoplastic liquid crystal polymer film 12 may be those made of the same type of such thermoplastic liquid crystal polymers, or may be those made of different types of such thermoplastic liquid crystal polymers.

Among these, an aromatic polyester resin that exhibits thermotropic liquid crystalline properties and has a melting point of 250° C. or more, preferably a melting point of 280° C. to 380° C. is preferably used. As such an aromatic polyester resin, aromatic polyester resins that are synthesized from monomers such as aromatic diols, aromatic carboxylic acids, and hydroxycarboxylic acids and that exhibit liquid crystallinity during melting are known. Representative examples thereof include, but are not particularly limited to, a polycondensate of ethylene terephthalate and para-hydroxybenzoic acid, a polycondensate of phenolic and phthalic acids and para-hydroxybenzoic acid, and a polycondensate of 2,6-hydroxynaphthoic acid and para-hydroxybenzoic acid. The aromatic polyester resins can be used singly or in any combination of two or more thereof at any ratio.

In preferable one aspect, an aromatic polyester resin at least having 6-hydroxy-2-naphthoic acid and a derivative thereof (hereinafter, sometimes simply referred to as “monomer component A”.) which is a basic structure, and having one or more monomer component(s) (hereinafter, sometimes simply referred to as “monomer component B”.) selected from the group consisting of para-hydroxybenzoic acid, terephthalic acid, isophthalic acid, 6-naphthalenedicarboxylic acid, 4,4′-biphenol, bisphenol A, hydroquinone, 4,4-dihydroxybiphenol, ethylene terephthalate and derivatives thereof is exemplified. The aromatic polyester resin forms an anisotropic molten phase in which linear chains of molecules are regularly aligned in a molten state, typically exhibits thermotropic liquid crystalline properties, and has excellent basic performance such as mechanical characteristics, electrical characteristics, high frequency characteristics, heat resistance, and hygroscopicity.

The aromatic polyester resin of preferable one aspect, described above, may employ any constitution as long as it has the monomer component A and the monomer component B as essential units. For example, it may have two or more monomer components A, or three or more monomer components A. The aromatic polyester resin of preferable one aspect, described above, may contain other monomer component (hereinafter, sometimes simply referred to as “monomer component C”.) other than the monomer component A and the monomer component B. That is, the aromatic polyester resin of preferable one aspect, described above, may be a binary or higher polycondensate consisting of only the monomer component A and the monomer component B, or may be a ternary or higher polycondensate consisting of the monomer component A, the monomer component B, and monomer component C. Other monomer components are other than the monomer component A and the monomer component B described above, and specific examples thereof include aromatic or aliphatic dihydroxy compounds and derivatives thereof; aromatic or aliphatic dicarboxylic acid and derivatives thereof; aromatic hydroxycarboxylic acid and derivatives thereof; aromatic diamine, aromatic hydroxyamine, or aromatic aminocarboxylic acid and derivatives thereof, but are not particularly limited thereto. Such other monomer component can be used singly or in any combination of two or more thereof at any ratio.

As used herein, the “derivatives” means those which have a modifying group such as a halogen atom (e.g., a fluorine atom, a chlorine atom, a bromine atom, and an iodine atom), an alkyl group having 1 to 5 carbon atoms (e.g., a methyl group, an ethyl group, an n-propyl group, an isopropyl group, an n-butyl group, an isobutyl group, an s-butyl group, and a t-butyl group), an aryl group such as a phenyl group, a hydroxyl group, an alkoxy group having 1 to 5 carbon atoms (e.g., a methoxy group and an ethoxy group), a carbonyl group, —O—, —S—, and —CH₂—introduced in a part of the monomer components described above (hereinafter, also referred to as “monomer component having a substituent”). Here, the “derivatives” may be acylated products, ester derivatives, or ester forming monomers such as acid halides, of the monomer components A and B, which may have a modifying group described above.

Examples of particularly preferable one aspect include a binary polycondensate of para-hydroxybenzoic acid and derivatives thereof, and 6-hydroxy-2-naphthoic acid and derivatives thereof; a ternary or higher polycondensate of para-hydroxybenzoic acid and derivatives thereof, 6-hydroxy-2-naphthoic acid and derivatives thereof, and the monomer component C; a ternary or higher polycondensate of para-hydroxybenzoic acid and derivatives thereof, 6-hydroxy-2-naphthoic acid and derivatives thereof, and at least one selected from the group consisting of terephthalic acid, isophthalic acid, 6-naphthalenedicarboxylic acid, 4,4′-biphenol, bisphenol A, hydroquinone, 4,4-dihydroxybiphenol, ethylene terephthalate, and derivatives thereof; a quaternary or higher polycondensate of para-hydroxybenzoic acid and derivatives thereof, 6-hydroxy-2-naphthoic acid and derivatives thereof, at least one selected from the group consisting of terephthalic acid, isophthalic acid, 6-naphthalenedicarboxylic acid, 4,4′-biphenol, bisphenol A, hydroquinone, 4,4-dihydroxybiphenol, ethylene terephthalate, and derivatives thereof, and one or more monomer components C. These can be obtained as having a relatively low melting point as compared with, for example, a homopolymer of para-hydroxybenzoic acid, and thus, the thermoplastic liquid crystal polymer using these polymers has excellent fabricability in the thermocompression bonding to an adherend.

From the viewpoint of reducing the melting point of the aromatic polyester resin, increasing the fabricability of the thermoplastic liquid crystal polymer films 11 and 12 in the thermocompression bonding to an adherend, obtaining high peel strength when the thermoplastic liquid crystal polymer films 11 and 12 are thermocompression bonded to a metal foil, or the like, the content in terms of molar ratio of the monomer component A to the aromatic polyester resin is preferably 10 mol % or more and 70 mol % or less, more preferably 10 mol % or more and 50 mol % or less, further preferably 10 mol % or more and 40 mol % or less, and still more preferably 15 mol % or more and 30 mol % or less. Similarly, the content in terms of molar ratio of the monomer component B to the aromatic polyester resin is preferably 30 mol % or more and 90 mol % or less, more preferably 50 mol % or more and 90 mol % or less, further preferably 60 mol % or more and 90 mol % or less, and still more preferably 70 mol % or more and 85 mol % or less. The content of the monomer component C that may be contained in the aromatic polyester resin is preferably 10% by mass or less, more preferably 8% by mass or less, further preferably 5% by mass or less, and preferably 3% by mass or less in terms of molar ratio.

A known method may be applied to the synthetic method of the aromatic polyester resin without particular limitation. A known polycondensation method to form ester bonds by the monomer components described above, such as melt polymerization, a melt acidolysis method, and a slurry polymerization method can be applied. When these polymerization methods are applied, an acylation or acetylation step may be performed in accordance with a conventional method.

The thermoplastic liquid crystal polymer films 11 and 12 each further contain an inorganic filler. The thermoplastic liquid crystal polymer films 11 and 12, which each contains an inorganic filler, thus can be realized to have a reduced coefficient of linear thermal expansion, and especially in the present embodiment, is effectively reduced in coefficient of linear thermal expansion in a ZD direction (thickness direction) and thus is particularly useful for, for example, rigid substrate applications in which multilayer laminates are required.

As the inorganic filler, those known in the art may be used, and the type thereof is not particularly limited. Examples include kaolin, fired kaolin, fired clay, unfired clay, silica (e.g., natural silica, fused silica, amorphous silica, hollow silica, wet silica, synthetic silica, and aerosil), aluminum compounds (e.g., boehmite, aluminum hydroxide, alumina, hydrotalcite, aluminum borate, and aluminum nitride), magnesium compounds (e.g., magnesium aluminometasilicate, magnesium carbonate, magnesium oxide, and magnesium hydroxide), calcium compounds (e.g., calcium carbonate, calcium hydroxide, calcium sulfate, calcium sulfite, and calcium borate), molybdenum compounds (e.g., molybdenum oxide and zinc molybdate), talc (e.g., natural talc and fired talc), mica, titanium oxide, zinc oxide, zirconium oxide, barium sulfate, zinc borate, barium metaborate, sodium borate, boron nitride, aggregated boron nitride, silicon nitride, carbon nitride, strontium titanate, barium titanate, and stannate such as zinc stannate, but are not particularly limited thereto. The inorganic filler can be used singly or in combinations of two or more thereof. Among these, silica is preferable from the viewpoint of dielectric characteristics and the like. The thermoplastic liquid crystal polymer film 11 and the thermoplastic liquid crystal polymer film 12 may comprise the same type of such inorganic fillers, or may comprise different types of such inorganic fillers.

The inorganic filler here used may be one subjected to surface treatment known in the art. The surface treatment can allow for enhancements in moisture resistance, adhesion strength, dispersibility, and the like. Examples of the surface treatment agent include a silane coupling agent, a titanate coupling agent, sulfonate, carboxylate, and phosphate, but are not particularly limited thereto.

The median diameter (d50) of the inorganic filler can be appropriately set depending on the desired performance, and is not particularly limited. The d50 of the inorganic filler is preferably 0.01 μm or more and 50 μm or less, more preferably 0.03 μm or more and 50 μm or less, and further preferably 0.1 μm or more and 50 μm or less from the viewpoint of kneading ability and handleability in preparation, and the effect of reducing the coefficients of linear thermal expansion. The inorganic fillers contained in the thermoplastic liquid crystal polymer films 11 and 12 may be the same as or different from each other in terms of d50.

The content of the inorganic filler can be appropriately set depending on the desired performance in consideration of the blending balance with other essential component and optional component, and is not particularly limited. The content of the inorganic filler in terms of solid content based on the total amount of the thermoplastic liquid crystal polymer films 11 and 12 is preferably 1% by mass or more and 45% by mass or less in total, more preferably 3% by mass or more and 40% by mass or less in total, and further preferably 5% by mass or more and 35% by mass or less in total, from the viewpoint of kneading ability and handleability in preparation, and the effect of reducing the coefficients of linear thermal expansion. In the present embodiment, a dry laminate L is adopted in which inorganic filler-containing thermoplastic liquid crystal polymer films 11 and 12 and a woven fabric of an inorganic fiber 21 are thermocompression bonded, and thus the proportion of filling of the inorganic filler can be kept relatively low when desired coefficients of linear thermal expansion in the MD direction, the TD direction, and the ZD direction are obtained, and as a result, the content of the thermoplastic liquid crystal polymer can be kept relatively high and thus dielectric characteristics can be kept high in a high frequency area.

The thermoplastic liquid crystal polymer films 11 and 12 may each contain a resin component other than the thermoplastic liquid crystal polymer described above, for example, a thermosetting resin and/or a thermoplastic resin, within a range not excessively impairing the effects of the present invention. The thermoplastic liquid crystal polymer films 11 and 12 may each contain additives known in the art, for example, release improving agents such as higher fatty acids having 10 to 25 carbon atoms, higher fatty acid esters, higher fatty acid amide, higher fatty acid metal salts, polysiloxane, and fluorine resins; colorants such as dyes and pigments; organic fillers; antioxidants; thermal stabilizers; light stabilizers; ultraviolet absorbers; flame retardants; antistatic agents; surfactants; anticorrosives; defoaming agents; and fluorescent agents, within a range not excessively impairing the effects of the present invention. These additives can be used each one alone or in combination of two or more. These additives can be contained in a molten resin composition during formation of each of the thermoplastic liquid crystal polymer films 11 and 12. The contents of such resin component and additive are not particularly limited, but are preferably each 0.01 to 10% by mass, more preferably each 0.1 to 7% by mass, and further preferably each 0.5 to 5% by mass based on a total amount of the thermoplastic liquid crystal polymer films 11 and 12, from the viewpoint of fabricability, thermal stability, and the like.

The woven fabric of an inorganic fiber 21 is a fabric obtained by weaving an inorganic fiber. The woven fabric of an inorganic fiber 21 can be thermocompression bonded with the thermoplastic liquid crystal polymer films 11 and 12 to thereby allow the coefficients of linear thermal expansion in the MD direction and the TD direction to be effectively reduced. Examples of such an inorganic fiber include glass fibers such as E-glass, D-glass, L-glass, M-glass, S-glass, T-glass, Q-glass, UN-glass, NE-glass, and spherical glass, inorganic fibers other than glass, such as quartz, and ceramic fibers such as silica, but are not particularly limited thereto. The woven fabric 21 of such an inorganic fiber is suitably a woven fabric subjected to opening treatment or packing treatment, from the viewpoint of dimensional stability. Among these, a glass cloth is preferable from the viewpoint of mechanical strength, dimensional stability, water absorbability, and the like. A glass cloth subjected to opening treatment or packing treatment is preferable from the viewpoint of increasing the thermocompression bonding properties of the thermoplastic liquid crystal polymer films 11 and 12. A glass cloth subjected to surface treatment with a silane coupling agent or the like, for example, epoxy silane treatment or amino silane treatment can also be suitably used. The woven fabric 21 can be used singly or in appropriate combinations of two or more kinds thereof.

The thickness of the woven fabric 21 can be appropriately set depending on the desired performance, and is not particularly limited. The thickness is preferably 10 to 300 μm, more preferably 10 to 200 μm, and further preferably 15 to 180 μm from the viewpoint of lamination ability, processability, mechanical strength, and the like.

The total thickness of the insulating material for a circuit substrate 100 (dry laminate L) can be appropriately set depending on the desired performance, and is not particularly limited. The total thickness is preferably 30 to 500 μm, more preferably 50 to 400 μm, further preferably 70 to 300 μm, and particularly preferably 90 to 250 μm from the viewpoint of lamination ability, processability, mechanical strength, and the like.

The insulating material for a circuit substrate 100 of the present embodiment, in which the above configuration is adopted, thus has a significant effect in that the insulating material, although is low in coefficient of linear thermal expansion in all the MD direction, the TD direction, and the ZD direction, has excellent dielectric characteristics in a high frequency area, and is easily manufactured and has excellent productivity.

The average coefficient of linear thermal expansion (CTE, α2, 23 to 200° C.) of the insulating material for a circuit substrate 100 of the present embodiment in the MD direction is not particularly limited, but is preferably 5 ppm/K or more and 25 ppm/K or less, more preferably 7 ppm/K or more and 24 ppm/K or less, and further preferably 9 ppm/K or more and 23 ppm/K or less from the viewpoint of increasing the adhesiveness to a metal foil. Similarly, the average coefficient of linear thermal expansion (CTE, α2, 23 to 200° C.) in the TD direction is preferably 5 ppm/K or more and 25 ppm/K or less, more preferably 7 ppm/K or more and 24 ppm/K or less, and further preferably 9 ppm/K or more and 23 ppm/K or less. On the other hand, the average coefficient of linear thermal expansion (CTE, α2, 23 to 200° C.) in the ZD direction is preferably 10 ppm/K or more and 100 ppm/K or less, more preferably 15 ppm/K or more and 98 ppm/K or less, and further preferably 20 ppm/K or more and 95 ppm/K or less. The coefficient of linear thermal expansion is herein measured by a TMA method according to JIS K7197 and the average coefficient of linear thermal expansion, as used herein, refers to an average value of the coefficient of linear thermal expansion at 23 to 200° C. as measured by the relevant method. To observe a value from which the thermal history has been eliminated, the coefficient of linear thermal expansion, here measured, refers to a value obtained when the insulating material for a circuit substrate 100 is heated at a temperature rising rate of 5° C./min (1st heating), cooled to the measurement environment temperature (23° C.) (1st cooling), and then heated for the second time at a temperature rising rate of 5° C./min (2nd heating). Other specific measurement conditions are in accordance with conditions described in the Examples below.

The dielectric characteristics of the insulating material for a circuit substrate 100 of the present embodiment can be appropriately set depending on the desired performance, and are not particularly limited. From the viewpoint of obtaining higher dielectric characteristics, the relative dielectric constant εᵣ (36 GHz) is preferably 3.0 or more and 3.7 or less, and more preferably 3.0 to 3.5. Similarly, the dielectric loss tangent tan δ (36 GHz) is preferably 0.0010 or more and 0.0050 or less, more preferably 0.0010 or more and 0.0045 or less. As used herein, the relative dielectric constant εᵣ and the dielectric loss tangent tan δ refer to respective values at 36 GHz as measured by a cavity resonator perturbation method according to JIS K6471. Other specific measurement conditions are in accordance with conditions described in the Examples below.

### Method for Manufacturing Insulating Material for Circuit Substrate

FIG. 2 is a flow chart of one example of a method for manufacturing an insulating material for a circuit substrate 100 of the present embodiment. The manufacturing method comprises at least a step (S1) of preparing the thermoplastic liquid crystal polymer films 11 and 12 each containing an inorganic filler, a step (S2) of preparing the woven fabric of an inorganic fiber 21, and a step (S3) of laminating the thermoplastic liquid crystal polymer films 11 and 12 and the woven fabric 21, and heating and pressurizing the resultant, to thereby form a dry laminate L in which the thermoplastic liquid crystal polymer films 11 and 12 and the woven fabric 21 are thermocompression bonded.

In the step S1, the inorganic filler-containing thermoplastic liquid crystal polymer films 11 and 12 are prepared. A commercial product can be used for such films, and such films can be each manufactured by a method known in the art. In preferable one aspect, for example, a method is adopted in which a resin composition containing the thermoplastic liquid crystal polymer and the inorganic filler described above is prepared (S1a) and the resin composition is formed into a film (S1b), to thereby obtain the thermoplastic liquid crystal polymer films 11 and 12 each containing the inorganic filler.

The resin composition may be prepared in accordance with a conventional method, and is not particularly limited. The components described above can be manufactured and processed by a known method such as kneading, melt-kneading, granulation, extrusion, and pressing or injection molding. When melt-kneading is performed, commonly used uniaxial or biaxial extruders or kneading apparatuses such as various kneaders can be used. When various components are supplied to these melt-kneading apparatuses, the liquid crystal polymer, other resin component, the inorganic filler, the additive, and the like may be dry blended in advance with a mixing apparatus such as a tumbler and a Henschel mixer. Upon melt-kneading, the cylinder set temperature of the kneading apparatus may be appropriately set without particular limitation, and is typically preferably within a range of the melting point of the liquid crystal polymer or more and 360° C. or less, and more preferably the melting point of the liquid crystal polymer +10° C. or more and 360° C. or less.

The resin composition, when prepared, may contain additives known in the art, for example, release improving agents such as higher fatty acids having 10 to carbon atoms, higher fatty acid esters, higher fatty acid amide, higher fatty acid metal salts, polysiloxane, and fluorine resins; colorants such as dyes and pigments; organic fillers; antioxidants; thermal stabilizers; light stabilizers; ultraviolet absorbers; flame retardants; antistatic agents; surfactants; anticorrosives; defoaming agents; and fluorescent agents, within a range not excessively impairing the effects of the present invention. These additives can be used each one alone or in combination of two or more. The content of the additive is not particularly limited, but is preferably 0.01 to 10% by mass, more preferably 0.1 to 7% by mass, and further preferably 0.5 to 5% by mass based on a total amount of the resin composition in terms of solid content, from the viewpoint of fabricability, thermal stability, and the like.

The method for forming the thermoplastic liquid crystal polymer films 11 and 12 is not particularly limited, but a melt extrusion method is preferably used. In preferable one aspect, a method is exemplified in which the resin composition described above is extruded and formed into a film by a melt extrusion film-forming method using a T-die (hereinafter, sometimes simply referred to as “T-die melt-extruded”.), thereafter, if necessary, a T-die melt-extruded film is subjected to heating and pressurizing treatment, and thus the predetermined thermoplastic liquid crystal polymer films 11 and 12 are obtained.

The set conditions of the melt-extrusion may be appropriately set depending on the type and composition of the resin composition to be used, the desired performance of the intended melt-extruded film, and the like, and are not particularly limited. Typically, the set temperature of the cylinder of the extruder is preferably 230 to 360° C., and more preferably 280 to 350° C. Also, for example, the slit clearance of the T-die may be appropriately set depending on the type and composition of the resin composition to be used, the desired performance of the intended melt-extruded film, and the like, and typically preferably 0.1 to 1.5 mm, and more preferably 0.1 to 0.5 mm, but is not particularly limited thereto.

The thickness of the melt-extruded film to be obtained can be appropriately set depending on the desired performance, and is not particularly limited. Considering the handleability and the productivity during T-die melt extrusion and the like, the thickness is preferably 10 μm or more and 500 μm or less, more preferably 20 μm or more and 300 μm or less, and further preferably 30 μm or more and 250 μm or less.

The melting point (melting temperature) of the melt-extruded film is not particularly limited, but the melting point (melting temperature) is preferably 200 to 400° C. from the viewpoint of the heat resistance, processability, and the like of the film, and is preferably 250 to 360° C., more preferably 260 to 355° C., further preferably 270 to 350° C., and particularly preferably 275 to 345° C. from the viewpoint of especially increasing the thermocompression bonding properties to the metal foil. As used herein, to observe a value from which the thermal history has been eliminated, the melting point of the melt-extruded film refers to a melting peak temperature in differential scanning calorimetry (DSC) when the melt-extruded film is heated at a temperature interval of 30 to 400° C. and at a temperature rising rate of 20° C./min with DSC8500 (manufactured by PerkinElmer Japan Co., Ltd.) (1st heating), then cooled at a temperature decreasing rate of 50° C./min (1st cooling), and then heated for the second time at a temperature rising rate of 20° C./min (2nd heating). Others are in accordance with the measurement conditions described in the Examples below.

When the above resin composition is T-die melt-extruded, typically, a T-die melt-extruded film having a coefficient of linear thermal expansion (CTE, α2) in the MD direction (Machine Direction) of −40 to 40 ppm/K and a coefficient of linear thermal expansion (CTE, α2) in the TD direction (Transverse Direction) of 50 to 120 ppm/K is likely to be obtained. The reason why such physical properties can be obtained is that the main chain of the liquid crystal polymer tends to be likely aligned in the MD direction during T-die melt-extrusion and the anisotropic melt phase of the liquid crystal polymer is present during T-die melt-extrusion.

Thus, in the step S1, a T-die melt-extruded film with a high degree of alignment (high anisotropy) is likely to be formed. Even such a T-die melt-extruded film having a high degree of alignment can be relaxed in alignment (anisotropy) during thermocompression bonding described below, and can be used as it is for the thermoplastic liquid crystal polymer films 11 and 12, but can also reduce its alignment (anisotropy), if necessary, by being subjected to a pressurizing and heating step.

The heating and pressurizing treatment may be performed using a method known in the art such as contact type heat treatment and non-contact type heat treatment, and the type thereof is not particularly limited. Heat setting can be carried out using a known device such as a non-contact heater, an oven, a blowing apparatus, a heat roller, a cooling roller, a heat press, or a double belt heat press. At this time, heat treatment may be performed by placing a release film or a porous film known in the art on a surface of the T-die melt-extruded film, if necessary. When this heat treatment is performed, thermocompression molding in which a release film or a porous film is placed on both surfaces of the T-die melt-extruded film, which is subjected to thermocompression bonding by sandwiching it between a pair of endless belts of a double belt press, and then the release film or the porous film is removed is preferably used, from the viewpoint of controlling the alignment. Thermocompression molding may be performed with reference to, for example, Japanese Patent Laid-Open No. 2010-221694. The treatment temperature when the T-die melt-extruded film using the above resin composition is subjected to thermocompression molding between a pair of endless belts of a double belt press is preferably a temperature higher than the melting point of the liquid crystal polymer and not more than a temperature 70° C. higher than the melting point, more preferably not less than a temperature +5° C. higher than the melting point and not more than a temperature 60° C. higher than the melting point, and further preferably not less than a temperature +10° C. higher than the melting point and not more than a temperature 50° C. higher than the melting point, to control the crystalline state of the T-die melt-extruded film. The thermocompression bonding conditions can be appropriately set depending on the desired performance and are not particularly limited, but are preferably conditions of a surface pressure of 0.5 to 10 MPa and a heating temperature of 250 to 430° C., more preferably conditions of a surface pressure of 0.6 to 8 MPa and a heating temperature of 260 to 400° C., and further preferably conditions of a surface pressure of 0.7 to 6 MPa and a heating temperature of 270 to 370° C. On the other hand, when a non-contact heater or an oven is used, for example, thermocompression bonding is preferably performed under the conditions at 200 to 320° C. for 1 to 20 hours.

The thicknesses of the thermoplastic liquid crystal polymer films 11 and 12 prepared in step S1 can be appropriately set depending on the desired performance and are not particularly limited. Considering the handleability and the productivity during heating and pressurizing treatment and the like, the thicknesses are each preferably 5 μm or more and 300 μm or less, more preferably 10 μm or more and 250 μm or less, and further preferably 20 μm or more and 200 μm or less. The thicknesses of the thermoplastic liquid crystal polymer films 11 and 12 may be the same as or different from each other. In the present embodiment, a dry laminate L in which the thermoplastic liquid crystal polymer films 11 and 12 and the woven fabric 21 are thermocompression bonded is adopted, and therefore an advantage is that thick (e.g., thickness 200 μm or more) thermoplastic liquid crystal polymer films 11 and 12 which have not been able to be applied in a varnish impregnation process as a conventional technique can be applied.

The melting points (melting temperatures) of the thermoplastic liquid crystal polymer films 11 and 12 prepared in the step S1 are not particularly limited, but the melting points (melting temperatures) are each preferably 200 to 400° C. from the viewpoint of heat resistance, processability, and the like of the film, and preferably 250 to 360° C., more preferably 260 to 355° C., further preferably 270 to 350° C., and particularly preferably 275 to 345° C. especially from the viewpoint of increasing the thermocompression bonding properties to the metal foil. As used herein, the melting points of the thermoplastic liquid crystal polymer films 11 and 12 each refer to a value measured under the same measurement conditions as the melting point of the above melt-extruded film.

In the step S2, the woven fabric of an inorganic fiber 21 is prepared. A commercial product can be used for the woven fabric 21, and the woven fabric can be manufactured by a method known in the art. The step S2 may be performed before or at the same time as the step S1, or after the step S1.

In the step S3, a dry laminate L in which the thermoplastic liquid crystal polymer films 11 and 12 and the woven fabric 21 are thermocompression bonded is formed by laminating the thermoplastic liquid crystal polymer films 11 and 12, and the woven fabric 21, and heating and pressurizing the resultant. In the step S3, the dry laminate L is formed by thermocompression bonding the thermoplastic liquid crystal polymer films 11 and 12 and the woven fabric 21, and thus is high in process tolerance in manufacturing and excellent in productivity and is increased in degree of freedom of the product configuration, as compared with a conventional varnish impregnation process.

Examples of preferable one aspect of the step S3 include a method in which the thermoplastic liquid crystal polymer film 11, the woven fabric 21 and the thermoplastic liquid crystal polymer film 12 are stacked in this order into a laminate, and this laminate is heated and pressurized and subjected to thermocompression molding with being sandwiched with a press, a double belt press or the like. The processing temperature during thermocompression bonding can be appropriately set depending on the desired performance and is not particularly limited, but is preferably 200 to 400° C., more preferably 250 to 360° C., and further preferably 270 to 350° C. The processing temperature during thermocompression bonding is a value measured with the surface temperature of the thermoplastic liquid crystal polymer films 11 and 12 of the laminate described above. The pressurizing conditions here can be appropriately set depending on the desired performance and are not particularly limited, but, are, for example, conditions of a surface pressure of 0.5 to 10 MPa and 1 to 240 minutes, more preferably conditions of a surface pressure of 0.8 to 8 MPa and 1 to 120 minutes.

### Metal Foil-Clad Laminate

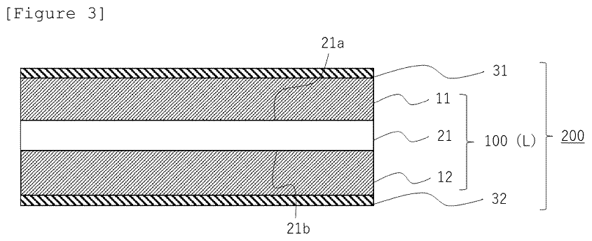

FIG. 3 is a schematic view of one example of a metal foil-clad laminate 200 of the present embodiment. The metal foil-clad laminate 200 of the present embodiment is a double-sided metal foil-clad laminate comprising the insulating material for a circuit substrate 100 (dry laminate L) described above and metal foils 31 and 32 provided on both surfaces of the insulating material for a circuit substrate 100. The present embodiment shows a double-sided metal foil-clad laminate, and the present invention can also be realized as an aspect in which a metal foil 31 (metal foil 32) is provided only on one surface of the insulating material for a circuit substrate 100.

Examples of the metal foils 31 and 32 include, but are not particularly limited to, gold, silver, copper, copper alloy, nickel, nickel alloy, aluminum, aluminum alloy, iron, and iron alloy. Among these, a copper foil, an aluminum foil, a stainless steel foil, and an alloy foil of copper and aluminum are preferred, and a copper foil is more preferred. As such a copper foil, any one manufactured by a rolling method, an electrolysis method, or the like may be used, and electrolytic copper foil and rolled copper foil which have a relatively high surface roughness are preferred. The thickness of the metal foils 31 and 32 may be appropriately set in accordance with the desired performance, and is not particularly limited. Typically, the thickness is preferably 1.5 to 1,000 μm, more preferably 2 to 500 μm, further preferably 5 to 150 μm, and particularly preferably 7 to 100 μm. As long as the function and effect of the present invention are not impaired, the metal foils 31 and 32 may be subjected to surface treatment such as chemical surface treatment such as acid washing. The types and the thicknesses of the metal foils 31 and 32 may be the same as or different from each other.

The method for providing the metal foils 31 and 32 on the surfaces of the insulating material for a circuit substrate 100 can be performed in accordance with a conventional method, and is not particularly limited. The method may be any one of methods in which the metal foils 31 and 32 are laminated on the insulating material for a circuit substrate 100 and then both layers are adhered or pressure bonded, physical methods (dry method) such as sputtering and vapor deposition, chemical methods (wet method) such as electroless plating and electrolytic plating after electroless plating, and methods for applying a metal paste. The metal foil-clad laminate 200 can also be obtained by heat pressing a laminate in which the insulating material for a circuit substrate 100 and one or more metal foils 31 and 32 are laminated, with, for example, a multi-stage press, a multi-stage vacuum press, a continuous molding machine, or an autoclave molding machine.

Examples of one preferable lamination method include a method in which the insulating material for a circuit substrate 100 and the metal foils 31 and 32 are stacked into a laminate in which the metal foils 31 and 32 are placed on the insulating material for a circuit substrate 100, and this laminate is subjected to thermocompression molding with being sandwiched between a pair of endless belts of a double belt press. As described above, the insulating material for a circuit substrate 100 to be used in the present embodiment is sufficiently reduced in anisotropy of the coefficients of linear thermal expansion in the MD direction and the TD direction and thus high peel strength to the metal foils 31 and 32 is obtained. The insulating material is also sufficiently reduced in coefficient of linear thermal expansion in the ZD direction, and thus is particularly useful for, for example, rigid substrate applications in which multilayer laminates are required.

The temperature during thermocompression bonding of the metal foils 31 and 32 can be appropriately set depending on the desired performance, and is not particularly limited, but is preferably not less than a temperature 50° C. lower than the melting point of the liquid crystal polymer and not more than a temperature 50° C. higher than the melting point, more preferably not less than a temperature 40° C. lower than the melting point and not more than a temperature 40° C. higher than the melting point, further preferably not less than a temperature 30° C. lower than the melting point and not more than a temperature 30° C. higher than the melting point, and particularly preferably not less than a temperature 20° C. lower than the melting point and not more than 20° C. higher than the melting point. The temperature during thermocompression bonding of the metal foils 31 and 32 is a value measured with the surface temperature of the insulating material for a circuit substrate 100 of the above-described. The thermocompression bonding conditions at this time can be appropriately set in accordance with the desired performance, but is not particularly limited thereto. For example, when a double belt press is used, the thermocompression bonding is preferably performed under the conditions of surface pressure of 0.5 to 10 MPa and a heating temperature of 200 to 360° C.

The metal foil-clad laminate 200 of the present embodiment may have another laminated structure or a further laminated structure, as long as including a thermocompression bonded body of a two layer structure of the insulating material for a circuit substrate 100, and the metal foils 31 and 32. The laminated structure may be a multilayer structure at least having the two layer structure described above, for example, a two layer structure such as metal foil 31/insulating material for a circuit substrate 100; a three layer structure such as metal foil 31/insulating material for a circuit substrate 100/metal foil 32 or insulating material for a circuit substrate 100/metal foil 31/insulating material for a circuit substrate 100; or a five layer structure such as metal foil 31/insulating material for a circuit substrate 100/metal foil 32/insulating material for a circuit substrate 100/metal foil 31. Also, a plurality of metal foil-clad laminates 200 (e.g., 2 to 50 laminates) may be laminated and thermocompression bonded.

In the metal foil-clad laminate 200 of the present embodiment, the peel strength between the insulating material for a circuit substrate 100 and the metal foils 31 and 32 is not particularly limited, but is preferably 1.0 (N/mm) or more, more preferably 1.1 (N/mm) or more, and further preferably 1.2 (N/mm) or more, from the viewpoint of providing further high peel strength. As described above, since the metal foil-clad laminate 200 of the present embodiment can realize higher peel strength than the conventional technique, for example, peeling between the insulating material for a circuit substrate 100 and the metal foils 31 and 32 can be suppressed in the heating step during manufacture of a substrate. In addition, since manufacturing conditions for excellent process tolerance and productivity can be applied to obtain the same peel strength as the conventional technique, the deterioration of the basic performance possessed by the liquid crystal polymer can be suppressed, while the same degree of peel strength as the conventional metal foil-clad laminate is maintained.

The metal foil-clad laminate 200 of the present embodiment can be used as a raw material for circuit substrates such as electronic circuit substrates or multilayer substrates, by performing pattern etching on at least a part of the metal foils 31 and 32. The metal foil-clad laminate 200 of the present embodiment, since having excellent dielectric characteristics in a high frequency area, having low coefficients of linear thermal expansion all in a MD direction, a TD direction, and a ZD direction, having excellent dimensional stability, being easily manufactured and having excellent productivity, is an especially useful raw material for flexible printed wiring boards (FPC) and the like in the fifth-generation mobile communication system (5G), millimeter wave radar, and the like.

### EXAMPLES

The feature of the present invention will be further described in detail below by way of Examples and Comparative Examples, but the present invention is not limited thereto in any way. That is, the materials, amounts used, proportions, contents of treatment, treatment procedures, and the like presented in the following Examples can be appropriately modified without departing from the gist of the present invention. The values of various manufacturing conditions and evaluation results in the following Examples have a meaning as a preferred upper limit value or a preferred lower limit value in the embodiment of the present invention, and the preferred numerical value range may be a range defined by a combination of the upper limit value or the lower limit value and the values of the following Examples or a combination of values in Examples.

### Examples 1

### Synthesis of Liquid Crystal Polymer

A reaction vessel equipped with a stirrer and a vacuum distillation apparatus was charged with p-hydroxybenzoic acid (74 mol %), 6-hydroxy-2-naphthoic acid (26 mol %), and 1.025-fold molar amount of acetic anhydride relative to the total monomer amount, and the reaction vessel was warmed to 150° C. under a nitrogen atmosphere and held for 30 minutes, and then immediately warmed to 190° C. while distilling off the byproduct acetic acid and held for 1 hour to obtain an acetylated reaction product. The obtained acetylated reaction product was warmed to 320° C. over 3.5 hours, then the pressure was reduced to 2.7 kPa over about 30 minutes to perform melt polycondensation, and the pressure was gradually returned to ordinary pressure to obtain a liquid crystal polymer solid. The obtained liquid crystal polymer solid was ground and granulated at 300° C. with a biaxial extruder to obtain pellets of an aromatic polyester-based liquid crystal polymer consisting of p-hydroxybenzoic acid and 6-hydroxy-2-naphthoic acid (PEs-LCP, molar ratio 74:26).

### Preparation of Resin Composition

Each of 80 parts by mass of the obtained liquid crystal polymer pellet and 20 parts by mass of fused silica (product name: Denka fused silica FB-5D, manufactured by Denka Co., Ltd.) was supplied, and mixed, reacted, and granulated with a biaxial extruder at 300° C. to obtain a resin composition (pellet) of Example 1.

### Manufacture of Thermoplastic Liquid Crystal Polymer Film

The obtained resin composition pellet of Example 1 was used and formed into a film by T-die casting at 300° C. to obtain the thermoplastic liquid crystal polymer film of Example 1 having a melting point of 280° C. and a thickness of 50.

### Manufacture of Insulating Material for Circuit Substrate

The obtained pair of thermoplastic liquid crystal polymer films of Example 1, in which a glass cloth (IPC No. #1037) was sandwiched therebetween, was subjected to thermocompression bonding treatment with heat pressing at 300° C. for 5 minutes, to obtain the insulating material for a circuit substrate of Example 1 having a melting point of 280° C. and a thickness of 100 μm.

### Examples 2 to 13

Each of the insulating materials for circuit substrates of Examples 2 to 13 was obtained in the same manner as in Example 1 except that the type and content of the inorganic filler to be used, the type and thickness of a woven fabric of an inorganic fiber to be used, and the thickness and the like of the insulating material for a circuit substrate were modified as described in Table 1.

### Comparative Example 1

The insulating material for a circuit substrate of Comparative Example 1 was obtained in the same manner as in Example 1 except that blending of fused silica was omitted.

### Comparative Example 2

The insulating material for a circuit substrate of Comparative Example 2 was obtained in the same manner as in Example 1 except that sandwiching of the glass cloth was omitted.

### Comparative Example 3

The insulating material for a circuit substrate of Comparative Example 3 was obtained in the same manner as in Example 1 except that blending of the fused silica and sandwiching of the glass cloth were omitted.

### Performance Evaluation

The insulating materials for circuit substrates of Example 1 to 13 and Comparative Example 1 to 3 were subjected to performance evaluation. The results are shown in Table 1. Measurement conditions were as follows.

### Median Diameter (d50) of Inorganic Filler

Measurement method: laser diffraction/scattering method

Measurement device: LA-500 (manufactured by Horiba Ltd.)

Measurement sample: inorganic filler dispersed in water with ultrasonic waves

Calculation method: creating a particle size distribution of an inorganic filler, on a volume basis, and calculating the median diameter (d50).

### Coefficient of Linear Thermal Expansion

Measurement device: TMA 4000SE (manufactured by NETZSCH Japan K.K.)

Measurement method: tension mode

Measurement conditions: sample size 20 mm×4 mm×thickness: 50 μm
temperature interval: 23 to 200° C. (2nd RUN)
temperature rising rate: 5° C./min
atmosphere: nitrogen (flow rate: 50 ml/min)
test load: 5 gf
* To observe a value from which the thermal history has been eliminated, the value at 2nd RUN was employed

### Relative Dielectric Constant ε_{R}, Dielectric Loss Tangent Tan δ (36 Ghz) Electrical Characteristics

Measurement method: cylindrical cavity resonator method

Measurement environment: temperature: 23° C., relative humidity: 50%

Measurement conditions: sample size: 15 mm×15 mm×thickness: 200 μm
cavity: 36 GHz

TABLE 1

| | | | | Example | Example | Example | Example | Example | Example |
|---|---|---|---|---|---|---|---|---|---|
| | | | | 1 | 2 | 3 | 4 | 5 | 6 |
| Insulating | Liquid | Type | — | PEs-LCP | PEs-LCP | PEs-LCP | PEs-LCP | PEs-LCP | PEs-LCP |
| material | crystal | Content | wt % | 80 | 80 | 80 | 80 | 80 | 80 |
| for circuit | polymer | | | | | | | | |
| substrate | Inorganic | Type | — | FB-5D | B703 | SG-200 | QSG-30 | SFP-30M | FB-40R |
| | filler | d50 | μm | 4.7 | 3.0 | 3.0 | 0.03 | 0.6 | 41.0 |
| | | Content | wt % | 20 | 20 | 20 | 20 | 20 | 20 |
| | Woven | Type | [IPC | #1037 | #1037 | #1037 | #1037 | #1037 | #1037 |
| | fabric of | | No.] | | | | | | |
| | inorganic | Thickness | μm | 25 | 25 | 25 | 25 | 25 | 25 |
| | fiber | | | | | | | | |
| | Dry | Total | μm | 100 | 100 | 100 | 100 | 100 | 100 |
| | laminate | thickness | | | | | | | |
| Performance | Coefficient | MD | ppm/K | 16 | 22 | 21 | 19 | 15 | 17 |
| | of linear | direction | | | | | | | |
| | thermal | TD | | 16 | 22 | 21 | 18 | 16 | 18 |
| | expansion | direction | | | | | | | |
| | | Thickness | | 70 | 92 | 88 | 76 | 60 | 79 |
| | | direction | | | | | | | |
| | Dielectric | Relative | — | 3.3 | 3.4 | 3.4 | 3.3 | 3.2 | 3.3 |
| | character- | dielectric | | | | | | | |
| | istics | constant | | | | | | | |
| | | Dielectric | — | 0.0042 | 0.0043 | 0.0040 | 0.0038 | 0.0040 | 0.0041 |
| | | loss | | | | | | | |
| | | tangent | | | | | | | |

| | | | | Example | Example | Example | Example | Example |
|---|---|---|---|---|---|---|---|---|
| | | | | 7 | 8 | 9 | 10 | 11 |
| Insulating | Liquid | Type | — | PEs-LCP | PEs-LCP | PEs-LCP | PEs-LCP | PEs-LCP |
| material | crystal | Content | wt % | 97 | 95 | 65 | 60 | 80 |
| for circuit | polymer | | | | | | | |
| substrate | Inorganic | Type | — | FB-5D | FB-5D | FB-5D | FB-5D | FB-5D |
| | filler | d50 | μm | 4.7 | 4.7 | 4.7 | 4.7 | 4.7 |
| | | Content | wt % | 3 | 5 | 35 | 40 | 20 |
| | Woven | Type | [IPC | #1037 | #1037 | #1037 | #1037 | #1017 |
| | fabric of | | No.] | | | | | |
| | inorganic | Thickness | μm | 25 | 25 | 25 | 25 | 15 |
| | fiber | | | | | | | |
| | Dry | Total | μm | 100 | 100 | 100 | 100 | 100 |
| | laminate | thickness | | | | | | |
| Performance | Coefficient | MD | ppm/K | 20 | 15 | 14 | 21 | 21 |
| | of linear | direction | | | | | | |
| | thermal | TD | | 19 | 17 | 16 | 22 | 20 |
| | expansion | direction | | | | | | |
| | | Thickness | | 95 | 88 | 31 | 63 | 73 |
| | | direction | | | | | | |
| | Dielectric | Relative | — | 3.3 | 3.1 | 3.2 | 3.3 | 3.2 |
| | character- | dielectric | | | | | | |
| | istics | constant | | | | | | |
| | | Dielectric | — | 0.0044 | 0.0039 | 0.0041 | 0.0039 | 0.0038 |
| | | loss | | | | | | |
| | | tangent | | | | | | |

| | | | | Example | Example | Comparative | Comparative | Comparative |
|---|---|---|---|---|---|---|---|---|
| | | | | 12 | 13 | Example 1 | Example 2 | Example 3 |
| Insulating | Liquid | Type | — | PEs-LCP | PEs-LCP | PEs-LCP | PEs-LCP | PEs-LCP |
| material | crystal | Content | wt % | 80 | 80 | 100 | 80 | 100 |
| for circuit | polymer | | | | | | | |
| substrate | Inorganic | Type | — | FB-5D | FB-5D | — | FB-5D | — |
| | filler | d50 | μm | 4.7 | 4.7 | — | 4.7 | — |
| | | Content | wt % | 20 | 20 | — | 20 | — |
| | Woven | Type | [IPC | #2116 | #7628 | #1037 | — | — |
| | fabric of | | No.] | | | | | |
| | inorganic | Thickness | μm | 95 | 180 | 25 | — | — |
| | fiber | | | | | | | |
| | Dry | Total | μm | 150 | 200 | 100 | 100 | 100 |
| | laminate | thickness | | | | | | |
| Performance | Coefficient | MD | ppm/K | 15 | 15 | 15 | 5 | 3 |
| | of linear | direction | | | | | | |
| | thermal | TD | | 17 | 16 | 19 | 91 | 88 |
| | expansion | direction | | | | | | |
| | | Thickness | | 68 | 71 | 219 | 71 | 223 |
| | | direction | | | | | | |
| | Dielectric | Relative | — | 3.2 | 3.2 | 3.3 | 3.2 | 3.1 |
| | character- | dielectric | | | | | | |
| | istics | constant | | | | | | |
| | | Dielectric | — | 0.0038 | 0.0042 | 0.0041 | 0.0018 | 0.0018 |
| | | loss | | | | | | |
| | | tangent | | | | | | |

* FB-5D Fused silica, manufactured by Denka Co., Ltd.
B703 aluminum hydroxide, manufactured by Nippon Light Metal Co., Ltd.
SG-200 Ultrafine talc, manufactured by Nippon Talc Co., Ltd.
QSG-30 Spherical fine silica particle, manufactured by Shin-Etsu Chemical Co., Ltd.
SFP-30M Fused silica, manufactured by Denka Co., Ltd.
FB-40R Fused silica, manufactured by Denka Co., Ltd.

### INDUSTRIAL APPLICABILITY

The insulating material for a circuit substrate of the present invention and the like can be widely and effectively utilized in applications such as electronic circuit substrates, multilayer substrates, high heat radiation substrates, flexible printed wiring boards, antenna substrates, optoelectronic hybrid substrates, and IC packages, and since having especially excellent high frequency characteristics and low dielectric properties, the insulating material for a circuit substrate of the present invention can be especially widely and effectively utilized as an insulating material for flexible printed wiring boards (FPC) and the like in the fifth-generation mobile communication system (5G), millimeter wave radar, and the like.

### REFERENCE SIGNS LIST

11 . . . thermoplastic liquid crystal polymer film
12 . . . thermoplastic liquid crystal polymer film
21 . . . woven fabric of inorganic fiber
21a . . . surface
21b . . . surface
31 . . . metal foil
32 . . . metal foil
100 . . . insulating material for circuit substrate
200 . . . metal foil-clad laminate
L . . . dry laminate

1. An insulating material for a circuit substrate, comprising a laminate having a thermoplastic liquid crystal polymer film and a woven fabric of an inorganic fiber, wherein
the thermoplastic liquid crystal polymer film contains an inorganic filler, and
the laminate is a dry laminate in which the thermoplastic liquid crystal polymer film and the woven fabric are thermocompression bonded.

2. The insulating material for a circuit substrate according to claim 1, wherein
the thermoplastic liquid crystal polymer film is a melt-extruded film.

3. The insulating material for a circuit substrate according to claim 1, wherein
the thermoplastic liquid crystal polymer film is a T-die melt-extruded film.

4. The insulating material for a circuit substrate according to claim 1, wherein
the inorganic filler contains silica.

5. The insulating material for a circuit substrate according to claim 1, wherein
the inorganic filler has a median diameter (d50) of 0.01 μm or more and 50 μm or less.

6. The insulating material for a circuit substrate according to claim 1, wherein
the thermoplastic liquid crystal polymer film contains 1% by mass or more and 45% by mass or less of the inorganic filler based on a total amount of the film.

7. The insulating material for a circuit substrate according to claim 1, wherein
the woven fabric has a thickness of 10 μm or more and 300 μm or less.

8. The insulating material for a circuit substrate according to claim 1, wherein
the woven fabric of the inorganic fiber is a glass cloth.

9. The insulating material for a circuit substrate according to claim 1, wherein
an average coefficient of linear thermal expansion at 23 to 200° C., as measured by a TMA method according to JIS K7197, is 5 ppm/K or more and 25 ppm/K or less in an in-plane direction and 10 ppm/K or more and 100 ppm/K or less in a thickness direction.

10. The insulating material for a circuit substrate according to claim 1, wherein
a relative dielectric constant εᵣ at 36 GHz, as measured by a cavity resonator perturbation method according to JIS K6471, is 3.0 or more and 3.7 or less.

11. The insulating material for a circuit substrate according to claim 1, wherein
a dielectric loss tangent tan δ at 36 GHz, as measured by a cavity resonator perturbation method according to JIS K6471, is 0.0010 or more and 0.0050 or less.

12. A method for manufacturing an insulating material for a circuit substrate, comprising
a step of preparing a thermoplastic liquid crystal polymer film containing an inorganic filler,
a step of preparing a woven fabric of an inorganic fiber, and
a step of laminating the thermoplastic liquid crystal polymer film and the woven fabric, and heating and pressurizing the resultant, to thereby form a dry laminate in which the thermoplastic liquid crystal polymer film and the woven fabric are thermocompression bonded.

13. The method for manufacturing an insulating material for a circuit substrate according to claim 12, wherein
the step of preparing the thermoplastic liquid crystal polymer film comprises
a composition preparation step of preparing a resin composition containing the thermoplastic liquid crystal polymer and the inorganic filler, and
a film formation step of molding the resin composition to thereby form the thermoplastic liquid crystal polymer film containing the inorganic filler.

14. A metal foil-clad laminate comprising
the insulating material for a circuit substrate according to claim 1, and a metal foil(s) provided on one surface and/or both surfaces of the insulating material for a circuit substrate.
